(19) United States
(12) Patent Application Publication
(10) Pub. No.: US 2010/0163181 A1
(43) Pub. Date: Jul. 1, 2010

(54) VACUUM PROCESSING APPARATUS

(75) Inventors: Hiroyuki KOBAYASHI, Kodaira (JP); Kenji MAEDA, Koganei (JP); Masaru IZAWA, Hino (JP); Makoto NAWATA, Kudamatsu (JP); Shingo KIMURA, Shuunan (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi High-Technologies Corporation

(21) Appl. No.: 12/369,767

(22) Filed: Feb. 12, 2009

(30) Foreign Application Priority Data
Dec. 26, 2008 (JP) 2008-332887

(51) Int. Cl. H01L 21/3065; B05C 11/00

(52) U.S. Cl. 156/345.24; 118/710

(57) ABSTRACT

There is provided a vacuum processing apparatus including a valve whose opening degree can be set to any size and a control computer which automatically controls a depressurizing rate. The vacuum processing apparatus can reduce the number of foreign particles adhered to a sample to be processed in the lock chamber and can improve the throughput at the same time.

### CLAIM OF PRIORITY

The present application claims priority from Japanese Patent Application JP 2008-332887 filed on Dec. 26, 2008, the content of which is hereby incorporated by reference into this application.

### FIELD OF THE INVENTION

The present invention relates to a vacuum processing apparatus and, more particularly, to a vacuum processing apparatus including lock chambers capable of switching between an ambient atmosphere and a vacuum atmosphere to carry a sample to be processed.

### BACKGROUND OF THE INVENTION

In the process of manufacturing a semiconductor device such as DRAM or microprocessor, plasma etching or plasma CVD is widely used. One of the targets in these semiconductor manufacturing apparatuses is to reduce the number of foreign particles adhered to the sample to be processed. For instance, when a foreign particle drops on the fine pattern of the sample to be processed during or before etching, etching is locally disturbed at that site. As a result, a failure such as disconnection occurs, thereby reducing the yield.

In the vacuum processing apparatus, the main location where a foreign particle adheres to the sample to be processed is a lock chamber for switching between vacuum and atmosphere besides a processing chamber. In order to suppress the generation of a foreign particle in the lock chamber, it is important that a gas flow should be made gentle at the time of switching from vacuum to atmosphere (to be referred to “venting”) and from atmosphere to vacuum (to be referred to “vacuuming”). As for vacuuming, for example, as described in Japanese Laid-open Patent Application No. 5-237361, there is proposed a valve for suppressing a sharp reduction in the inside pressure of a chamber by opening the valve slowly. This valve is designed to carry out the main evacuation while a turbulence of an air current is prevented at the time of initial evacuation by itself.

Further, as described in Japanese Laid-open Patent Application No. 11-40549, it is proposed that the depressurization rate should not exceed a predetermined value by installing a low-speed exhaust line having a low exhaust conductance and a high-speed exhaust line having a high exhaust conductance to carry out vacuum evacuation slowly and using the low-speed exhaust line at the time of starting vacuum evacuation. Japanese Laid-open Patent Application No. 11-40549 discloses an example in which an exhaust valve capable of binary control between a closed state and an open state and an exhaust conductance control valve are connected to one exhaust line in series and an example in which the above exhaust valve and the exhaust conductance control valve are connected to two respective exhaust lines in parallel. A description of a valve capable of controlling the exhaust conductance is also found in Japanese Laid-open Patent Application No. 2001-324030.

FIG. 13 shows an example of a conventionally well known vacuum exhaust system. Reference numeral 51 denotes a vent line, 52-3 denotes a valve installed in the vent line (to be referred to as “vent valve” hereinafter), 53 denotes a gas flow controller such as a regulator or mass flow controller, 61 denotes a vacuum transfer chamber, 63 denotes an atmosphere transfer chamber, 65 denotes a lock chamber, and 71 and 72 denote gate valves. An exhaust line 140 interconnecting the lock chamber 65 and a dry pump 42 has a high-speed exhaust line (main line) 141 for exhausting air at a high speed and a low-speed exhaust line (bypass line) 142 for exhausting air at a low speed at the time of starting vacuuming arranged in parallel in high-speed exhaust line 141. A valve having no function of controlling the opening and closing speeds is used as a valve 52-1 provided in the high-speed exhaust line 141 and a valve 52-2 provided in the low-speed exhaust line valve 142. This exhaust line structure is called “two-step exhaust structure”.

Further, a valve incorporating a main exhaust line and a bypass exhaust line (to be called “two-step exhaust valve” hereinafter) is also proposed. An example of this “two-step exhaust valve” is disclosed in Japanese Laid-Open Patent Application No. 2003-156171. This valve incorporates a high-speed exhaust line 141, a valve 52-1 for a high-speed exhaust line, a low-speed exhaust line 142 and a valve 52-2 for a low-speed exhaust line. Even when this two-step exhaust valve is used, there is no substantial difference between this valve and the two-step exhaust system of FIG. 13 in the prevention of scattering foreign matter and in the improvement of the exhaust speed.

### SUMMARY OF THE INVENTION

There is a trend toward the incorporation of multiple chambers in a vacuum processing apparatus such as a plasma processing apparatus. This is a system for connecting multiple processing chambers to one transfer system for carrying a sample to be processed. An advantage obtained by installing multiple processing chambers is that the number of samples which can be processed by one manufacturing apparatus is increased. Therefore, when the number of processing chambers to be connected to the transfer chamber is increased from 1 to 2, 3 and 4, the number of samples processed per unit time is desirably 2, 3 and 4 times compared to the number of samples when the number of processing chambers is 1. However, even when the number of processing chambers is increased, the number of samples to be processed per unit time is not increased to an expected level. One of the reasons for this is that it is difficult to improve the throughput of the lock chamber.

For example, in the two-step exhaust structure shown in FIG. 13, when the evacuation time is shortened by increasing the vacuuming speed, an air current in the lock chamber becomes fast, thereby increasing the total amount of scattering foreign particles. Therefore, the vacuuming speed cannot be increased easily, which is one of the obstacles to the improvement of the throughput in the lock chamber.

The reason that it is difficult to shorten the evacuation time in the conventional two-step exhaust structure is explained with reference to FIG. 14 and FIGS. 15 (15A, 15B and 15C). FIG. 14, (A) shows changes in the inside pressure of the lock chamber at the time of vacuuming, FIG. 14, (B) shows the depressurization rate of the inside of the lock chamber, and FIG. 15 show the timings of opening and closing the valve. In FIG. 14, vacuuming is started from the atmospheric pressure (about 100 kPa) and completed at about 100 Pa. FIG. 14 shows three evacuation patterns “a”, “b” and “c”, and the timings of the opening and closing the valve in these patterns correspond to FIG. 15A, FIG. 15B and FIG. 15C, respectively. “α” in FIGS. 15 (15A-15C) indicates the timing of opening and closing the valve 52-1 in the high-speed exhaust line in the two-state exhaust structure and “β” indicates the timing of opening and closing the valve 52-2 in the low-speed exhaust line in the two-stage exhaust structure. CLOSE on the longitudinal axis indicates that the valve is totally closed and OPEN indicates that the valve is fully opened. The condition “c” in FIG. 14 is first described. The condition “c” is that the lock chamber is evacuated from the atmospheric pressure to about 10 kPa (about 1/10 of the atmospheric pressure) by the low-speed exhaust line and then by the high-speed exhaust line when the inside pressure of the lock chamber reaches about 10 kPa (t3). When the inside pressure reaches about 100 Pa (t6), evacuation is completed. In this case, although the depressurization rate slight rises (d1, d2, respectively) right after vacuuming is started by the low-speed exhaust line and right after vacuuming is carried out by the high-speed exhaust line as shown in FIG. 14(B), it does not exceed a depressurization rate d0 (for example, 80 kPa/s) at which the amount of scattering foreign particles exceeds an acceptable value. Therefore, the risk of rolling foreign matter is very small.

Next, the condition “b” in FIG. 14 is described. The condition “b” is that vacuuming is carried out by the low-speed exhaust line from the atmospheric pressure to 50 kPa (about ½ of the atmospheric pressure) and then by switching to the high-speed exhaust line after the inside pressure reaches about 50 kPa (t2). In this case, the maximum depressurization rate (d1) right after vacuuming is started by the low-speed exhaust line falls below the risk borderline of rolling foreign matter (d0) like the condition “c”. However, at the timing of switching to the high-speed exhaust line, the maximum depressurization rate (d3) exceeds the risk borderline of rolling foreign matter (d0). Since the evacuation time (t2) of the low-speed exhaust line is shorter than the evacuation time (t3) of the low-speed exhaust line under the condition “c”, the time t5 when the inside pressure reaches 100 Pa is shorter than that of the condition “c”. The condition “a” in FIG. 14 shows that vacuuming is carried out by the high-speed exhaust line from the atmospheric pressure. In this case, although the time (t4) elapsed until the inside pressure reaches, for example, 100 Pa is shorter than the times (t5 and t6) elapsed until the inside pressure reaches 100 Pa under the condition “b” and the condition “c”, the maximum depressurization rate (d4) right after the start of vacuuming greatly exceeds the risk borderline of rolling foreign matter (d0). That is, when the exhaust line is switched to the high-speed exhaust line in the early stage from the start of vacuuming, the time elapsed until the inside pressure reaches a predetermined vacuum degree becomes short but the maximum depressurization rate right after the exhaust line is switched to the high-speed exhaust line becomes high, thereby increasing the amount of rolling foreign matter. That is to say, when the depressurization rate is reduced to a level at which foreign matter is not stirred up, the vacuuming time must be prolonged by the low-speed exhaust line with the result that the time elapsed until the end of vacuuming becomes long.

It is an object of the present invention to provide a vacuum processing apparatus which can improve the transport throughput of samples to be processed while the number of foreign particles adhered to the samples to be processed is reduced in a vacuum chamber capable of switching between a vacuum atmosphere and an ambient atmosphere such as a lock chamber.

A typical embodiment of the present invention is described below. That is, the present invention is a vacuum processing apparatus including:

a lock chamber capable of switching between a vacuum atmosphere and an ambient atmosphere;

a vacuum pump for reducing the inside pressure of the lock chamber;

a valve installed in an exhaust line for connecting the vacuum pump to the lock chamber; and

control means for controlling the opening degree of the valve,

wherein the exhaust line is composed of only a single line, the valve installed in the exhaust line is composed of only a single opening variable valve, and

wherein the control means controls the opening degree of the valve from a totally closed state to a fully opened state while it controls a depressurization rate to a substantially constant value so as to reduce the inside pressure of the lock chamber from the ambient atmosphere.

According to the present invention, it is possible to suppress the generation of foreign particles caused by vacuuming by controlling the evacuation speed, greatly shorten the time required for evacuation, improve the throughput and increase the operation rates of semiconductor manufacturing and inspection apparatuses and productivity.

### BRIEF DESCRIPTION OF THE DRAWINGS

FIG. 1 is a longitudinal sectional view of a lock chamber provided in a vacuum processing apparatus according to Embodiment 1 of the present invention;

FIGS. 2 (2A-2C) are diagrams of the plasma processing apparatus shown in FIG. 1 and a control computer, wherein FIG. 2A is a top view of the plasma processing apparatus, FIG. 2B is a B-B sectional view of the plasma etching apparatus shown in FIG. 2A, and FIG. 2C shows an example of the functional blocks of the control computer shown in FIG. 2A;

FIGS. 3 (3A-3C) are diagrams of an example of an opening variable valve installed in the vacuum exhaust system of FIG. 1, wherein FIG. 3A shows that the opening degree of the opening variable valve is 0% (totally closed), FIG. 3B shows that the opening degree of the opening variable valve is x % (x=y [degrees]/90 [degrees]×100), and FIG. 3C shows that the opening degree of the opening variable valve is 100% (fully opened);

FIGS. 4 (4A-4C) are diagrams of another example of the opening variable valve installed in the vacuum exhaust system of FIG. 1, wherein FIG. 4A shows that the opening degree of the valve is 0% (totally closed), FIG. 4B shows that the opening degree of the valve is x % (x=y [degrees]/90 [degrees]×100), and FIG. 4C shows that the opening degree of the valve is 100% (fully opened);

FIG. 5 shows an example of the opening control pattern of the opening variable valve of this embodiment;

FIG. 6 shows another example of the opening control pattern of the opening variable valve of this embodiment;

FIGS. 7 (7A-7C) show different examples of a vacuuming recipe in this embodiment;

FIG. 8 is a flow diagram showing the method of preparing the control recipe (vacuuming recipe) of this embodiment;

FIG. 9 shows the correlation between the depressurization rate and the number of foreign substances dropped on a wafer installed in the lock chamber actually measured by experiments;

FIGS. 10 (10A-10c) are diagrams of a gas flow velocity, wherein FIG. 10A shows when the capacity of the lock chamber is 5 liters, FIG. 10B shows when the capacity of the lock chamber is 10 liters, and FIG. 10C shows when the capacity of the lock chamber is 20 liters;

FIG. 11 shows the relationship between the capacity of the lock chamber and the depressurization rate;

FIG. 12 is a flow diagram showing the method of cleaning the lock chamber making use of the opening variable valve according to Embodiment 2 of the present invention;

FIG. 13 is a longitudinal sectional view of a lock chamber having a conventionally known two-step exhaust structure;

FIG. 14 shows diagrams of changes in the inside pressure of the lock chamber at the time of vacuuming and the depressurization rate of the inside of the lock chamber in the structure of FIG. 13, respectively; and

FIGS. 15 (15A-15c) show the timings of opening and closing the valve corresponding to the evacuation pattern “a”, the evacuation pattern “b” and the evacuation pattern “c” in FIGS. 14, (A) and (B), respectively.

### DETAILED DESCRIPTION OF THE PREFERRED EMBODIMENTS

Preferred embodiments of the present invention will be described hereunder with reference to the accompanying drawings.

### Embodiment 1

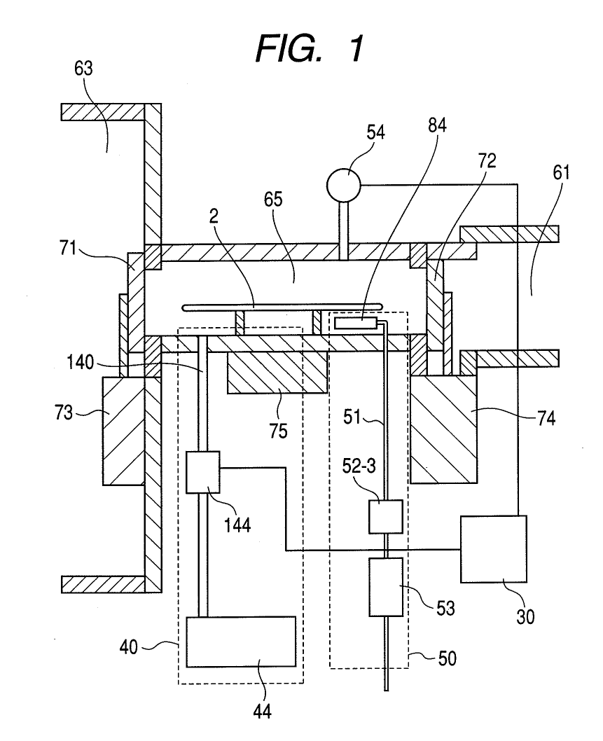

With reference to FIGS. 1 to 12, a vacuum processing apparatus according to Embodiment 1 of the present invention will be described.

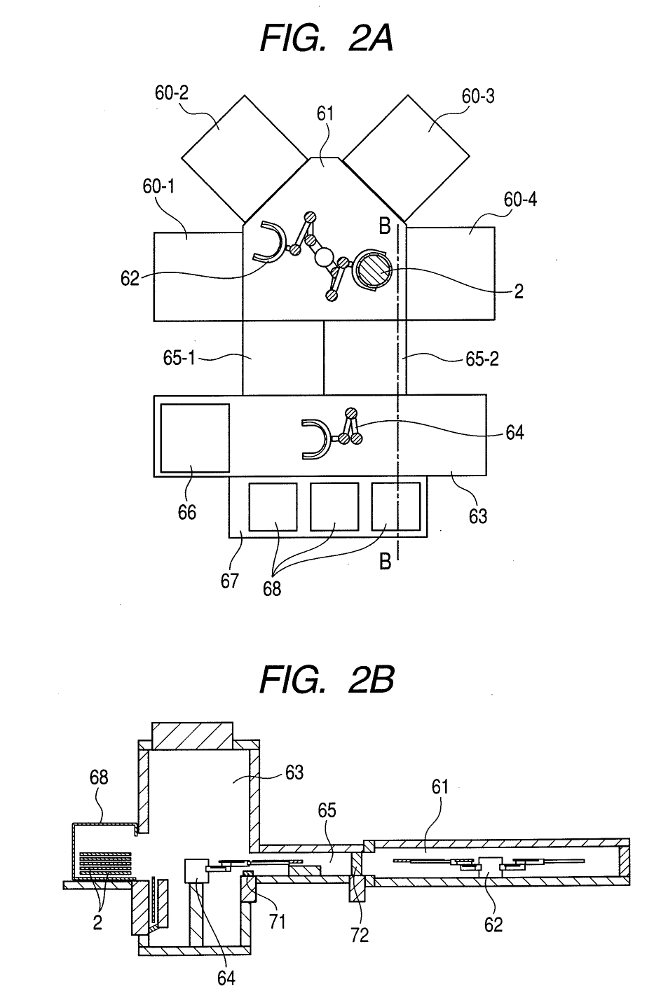

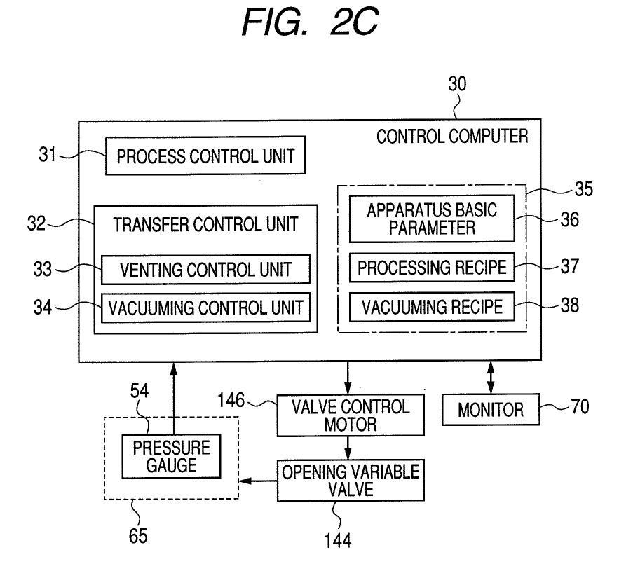

FIG. 1 is a schematic diagram of a lock chamber provided in the vacuum processing apparatus according to the Embodiment 1. FIG. 2A is a schematic top view of a plasma processing apparatus, and FIG. 2B is a B-B sectional view of the plasma etching apparatus shown in FIG. 2A. In FIG. 2B, plasma processing chambers are not shown. Further, FIG. 2C is a diagram of an example of the functional blocks of a control computer.

As shown in FIGS. 2A and 2B, in the plasma processing apparatus of this embodiment, four vacuum processing chambers, that is, plasma processing chambers 60 (60-1 to 60-4) are connected to a vacuum transfer chamber 61. Each of the plasma processing chambers is connected to a vacuum pump (not shown) for depressurization. The vacuum transfer chamber 61 having a vacuum transfer robot 62 and an atmosphere transfer chamber 63 having an atmosphere transfer robot 64 are connected to each other through two lock chambers 65 (65-1, 65-2). For example, the lock chamber 65-1 is used as a load lock chamber and the lock chamber 65-2 is used as an unload lock chamber. The load lock chamber is used to carry a sample (a wafer) 2 to be processed from the atmosphere transfer chamber to the vacuum transfer chamber whereas the unload lock chamber is used to carry the sample 2 to be processed from the vacuum transfer chamber to the atmosphere transfer chamber. As a matter of course, each of the lock chambers may serve as a load and unload lock chamber. The atmosphere transfer robot 64 carries samples 2 to be processed between hoops 68 placed at a wafer station 67 and a wafer aligner 66 and the lock chambers 65.

As shown in FIG. 1, a vacuum exhaust system 40 including a vacuum pump (a dry pump) 44 for depressurization and an opening variable valve 144 installed in an exhaust line 140 for connecting this vacuum pump to the lock chamber is connected to each of the lock chambers 65. That is, each of the lock chamber 65-1 and the lock chamber 65-2 is connected to the vacuum pump 44 by only a single exhaust line, respectively, and the opening variable valve 144 is installed in each of these exhaust lines.

The lock chambers are each connected to a vent gas supply system 50 including a gas diffuser 85, a vent valve 52-3 and a regulator 53. Reference numeral 30 denotes control means (control computer) for controlling the whole apparatus and is able to control the opening variable valves 144 as well. Further, a pressure gauge 54 is provided to measure the inside pressure of each of the lock chambers.

The control computer 30 has units (functions) each of which can be realized by executing programs with an arithmetic processing means. That is, as shown in FIG. 2C, the control computer 30 includes a process control unit 31 for integrally controlling the conveyance and processing of the sample 2 to be processed in the vacuum processing apparatus and a transfer control unit 32. The transfer control unit 32 includes a venting control unit 33 and a vacuuming control unit 34 and controls the vacuuming of the lock chambers and the venting of the lock chambers as well as the conveyance of the sample 2 to be processed. Data required for executing these programs is stored in a memory as a database 35. For example, the apparatus basic parameters 36 of the vacuum processing apparatus, a vacuum processing recipe 37 for the sample to be processed and a vacuuming recipe 38 are stored in the database. The process control unit 31 of the control computer 30 controls, by use of this data, the opening of the opening-degree variable valve 144 at the timing of vacuuming or venting the lock chamber so as to carry the sample to be processed. The vacuuming recipe 38 required for the vacuuming control unit 34 is set by an operator operating the vacuum processing apparatus through a monitor 70 having a GUI function. An example of this will be described hereinafter.

The lock chamber 65-1 and the lock chamber 65-2 are identical to each other in basic constitution shown in FIG. 1.

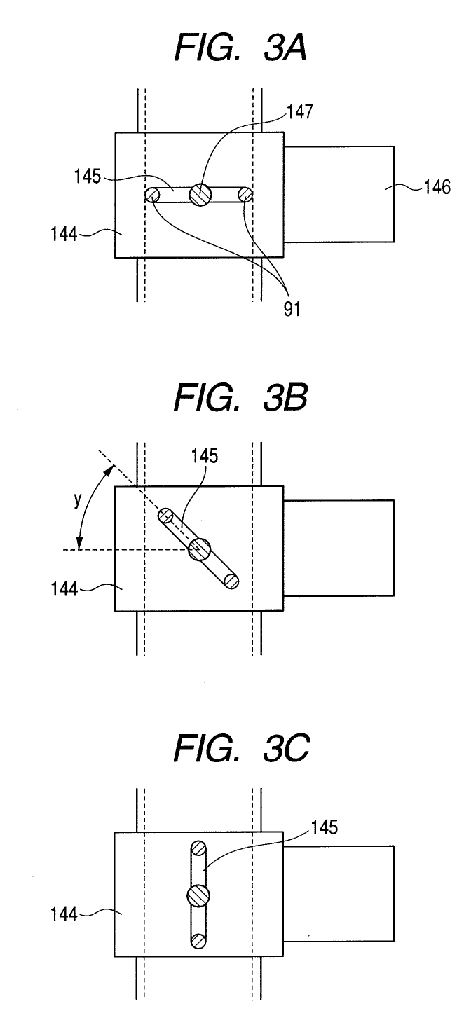

FIGS. 3 (3A to 3C) show an example of the opening variable valve 144 whose opening can be set to any size as an exhaust valve installed in the vacuum exhaust system. This valve is a butterfly type valve whose opening, that is, exhaust conductance can be adjusted by turning a valve plate 145 with a rotary shaft 147. The valve plate is turned by a servo motor 146 which can be controlled by the control computer 30. FIG. 3A shows that the opening of the valve plate is 0% (totally closed) and FIG. 3B shows that the opening degree is x % (x=y [degrees]/90 [degrees]×100), and FIG. 3C shows that the opening degree is 100% (fully opened). The exhaust line can be completely blocked by an O-ring 91 installed on the valve plate 145 when the opening degree is 0%.

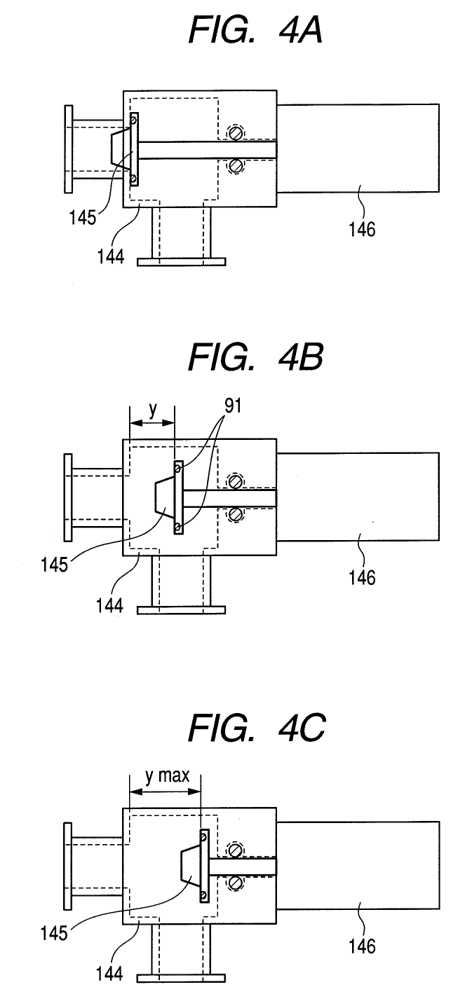

The opening variable valve does not need to be a butterfly type valve as shown in FIG. 3 if its opening degree can be adjusted to any size and may be an opening variable valve shown in FIGS. 4 (4A to 4C). The opening of the valve plate of this valve can be adjusted to any size by a servo motor 146. FIG. 4A shows that the opening degree of the valve plate is 0%, FIG. 4B shows that the opening degree is x % (x=y/ymax×100), and FIG. 4C shows that the opening degree is 100%.

Any valve is acceptable as the opening variable valve 144 as long as its opening degree can be controlled to any values as shown in FIGS. 3 and 4, and a gate type valve may also be used. However, it is desired that the valve should have an O-ring on the valve plate or a surface accepting the valve plate when the opening degree is 0% so that a gas flow can be cut off. If the valve has no function of sealing up a vacuum when the opening degree is 0%, an ordinary valve which can be set only OPEN and CLOSE must be installed in the exhaust line 140, in addition to the opening variable valve. This increases the number of required valves, thereby boosting costs.

Next, the method of setting the opening degree of the valve at the time of vacuuming is described. The control computer 30 can control the whole apparatus and includes the vacuuming control unit 34 for controlling the opening variable valve 144. The control of the opening degree of the opening variable valve 144 by the vacuuming control unit 34 is desirably carried out based on the measurement value of pressure obtained by the pressure gauge 54 of the lock chamber. After a predetermined opening control pattern is determined, a time control system for controlling the opening degree according to time elapsed from the start of vacuuming may be employed. Further, the vacuuming control unit for controlling the opening degree of the opening variable valve 144 may be separate from the control computer 30 so that a valve opening/closing start signal from the control computer 30 is received by the vacuuming control unit to carry out the fine control of the opening degree.

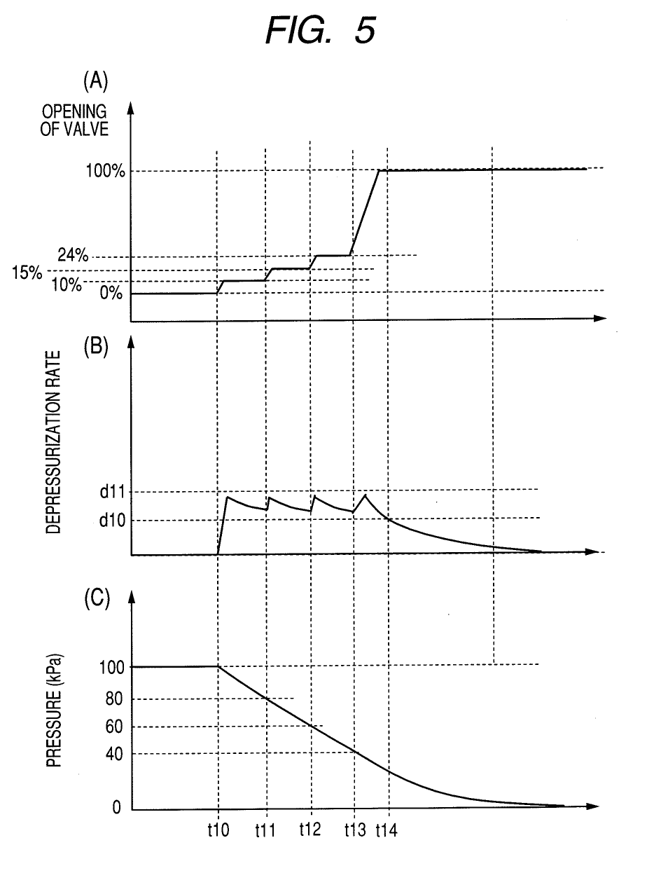

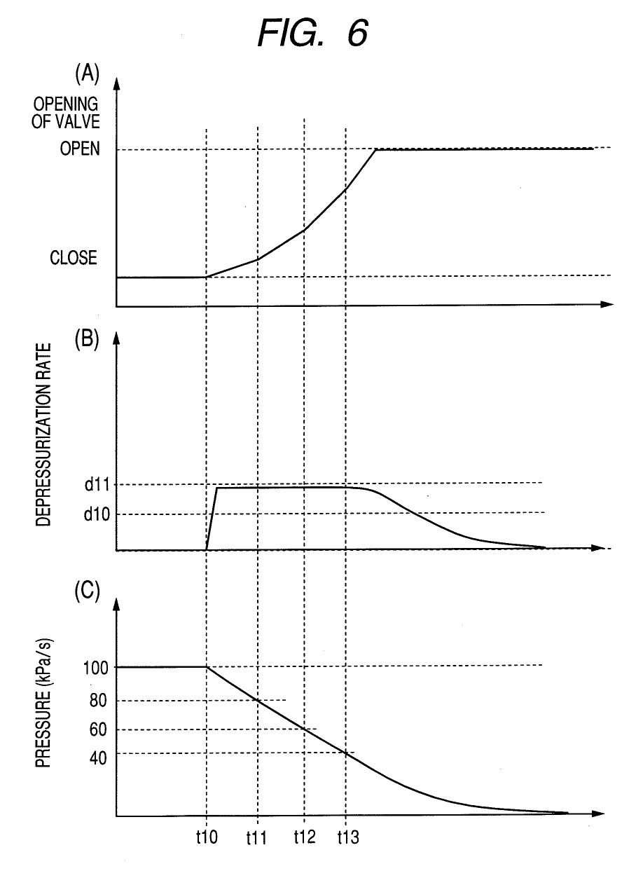

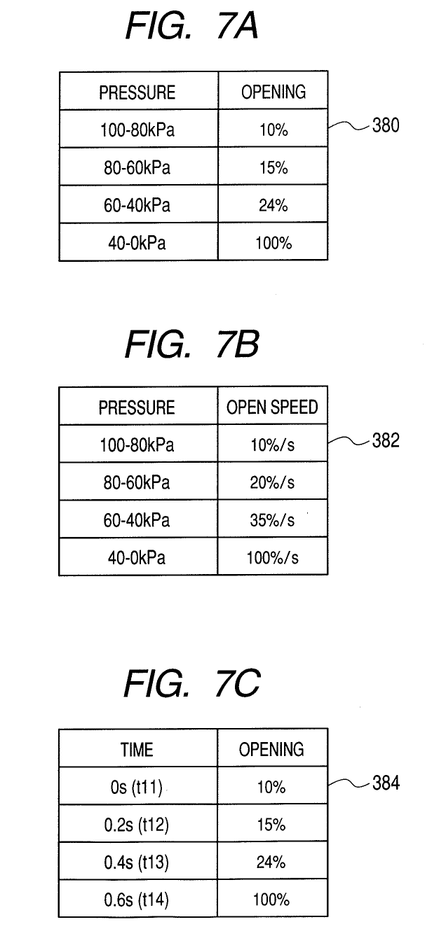

An example of the control of the opening degree of the opening variable valve 144 by the vacuuming control unit 34 of the control computer 30 will be described with reference to FIGS. 5 to 7. FIG. 5 and FIG. 6 show the control characteristics of the valve, and as data that provide the control characteristics of the valve, an example of the vacuuming recipe 38 is shown in FIGS. 7 (7A, 7B and 7C).

FIG. 5(A) shows the opening degree of the valve, FIG. 5(B) shows the depressurization rate of the inside of the lock chamber 65, and FIG. 5(C) shows the inside pressure of the lock chamber. In FIG. 5(B), d10 is the lower limit of depressurization rate and d11 is the upper limit of depressurization rate. For example, at the time point t10 of starting the vacuuming of the inside of the lock chamber 65, the opening degree of the valve is set to 10%. When the inside pressure of the lock chamber reaches 80 kPa (t11), the opening degree of the valve is set to 15%, and when the inside pressure of the lock chamber reaches 60 kPa (t12), the opening degree is set to 24%. Further, when the inside pressure of the lock chamber reaches 40 kPa or less (t13), the opening degree of the valve is set to 100%. By controlling the opening degree of the valve continuously or stepwise according to the inside pressure of the lock chamber, the depressurization rate of the inside of the lock chamber 65 can be adjusted to a substantially constant value close to the upper limit depressurization rate, that is, a value which does not exceed the predetermined upper limit depressurization rate d11 but exceeds the lower limit depressurization rate d10 as much as possible from the early stage after the start of vacuuming to the point of time when the valve is fully opened.

The upper limit depressurization rate d11 is a depressurization rate at which the total amount of rolling foreign particles in the lock chamber sharply increases.

Meanwhile, the lower limit depressurization rate d11 is a target value of the minimum depressurization rate for reducing the evacuation time of the lock chamber as much as possible. When the inside pressure of the lock chamber becomes low, if the opening degree of the valve is made largest, the depressurization rate does not exceed d10 (t14). That is, as long as the depressurization rate can exceed d10 by controlling the opening degree of the valve, the opening degree of the valve is set to less than 100%.

In the example of FIG. 5, the method of controlling the opening degree according to pressure is employed and a setting table (vacuuming recipe) is shown as the table 380 of FIG. 7A.

The vacuuming recipe may be set based on the OPEN speed and not the opening degree. This is shown in FIG. 6. FIG. 6, (A) shows the opening degree of the valve, FIG. 6, (B) shows the depressurization rate, and FIG. 6, (C) shows pressure. The setting table (vacuuming recipe) is shown as the table 382 of FIG. 7B. That is, the servo motor is controlled to increase the opening degree by 10% per unit time right after the start of vacuuming (t10). When the pressure reaches 80 kPa (t11), the OPEN speed is accelerated such that the opening degree is increased at a rate of 20%/s. When the pressure becomes 60 kPa or less (t12), the OPEN speed is set to 35%/s, and when the pressure becomes 40 kPa or less (t13), the opening degree is set to 100% at the maximum speed. As shown in FIG. 6(B), the depressurization rate is maintained at a substantially constant value right below the upper limit depressurization rate d11 from the early stage after the start of vacuuming to the point of time when the valve is fully opened. As for examples of the relationship between the opening degree and the OPEN speed, at t11, it is 10%×(t11−t10); at t12, it is 10%×(t11−t10)+20%×(t12−t11); and at t13, it is 10%×(t11−t10)+20%×(t12−t11)+35%×(t13−t12). That is, the opening degree is substantially controlled according to pressure in this system.

Even with the control method shown in FIG. 5, the depressurization rate can be controlled to a value smaller than the upper limit depressurization rate d11 and larger than the lower limit depressurization rate d10 as much as possible, that is, a substantially constant value close to the upper limit depressurization rate like the control method shown in FIG. 6. The example shown in FIG. 6 has an advantage that the depressurization rate can be linearly controlled. There is no big difference between them in the effect of preventing rolling foreign matter.

In the above examples, the opening degree of the valve is controlled according to pressure. However, the present invention is not limited to this. For example, after the relationship between the pressure and the opening degree is investigated in advance as shown in FIG. 5 and FIG. 7A or FIG. 6 and FIG. 7B, it may be converted into the relationship between the time and the opening degree to prepare a vacuuming recipe so that the opening degree of the valve is controlled by time in the mass-production site of a semiconductor device. For instance, as shown in FIG. 7C, the control computer may have the relationship between the elapse time from the start of vacuuming and the opening degree of the valve as a valve control recipe for vacuuming.

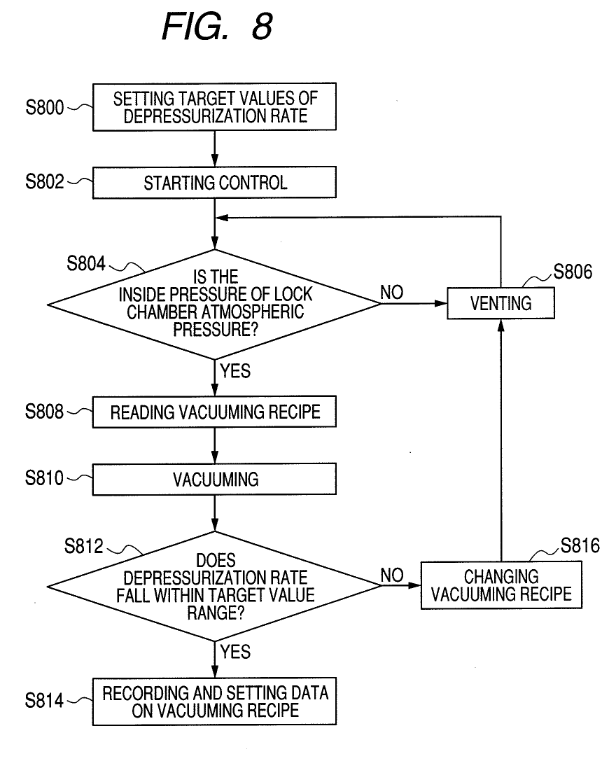

A description is subsequently given of the method of preparing the control recipe (vacuuming recipe) as shown in FIG. 7 with reference to FIG. 8. After the target values (lower limit of depressurization rate d10 and upper limit of depressurization rate d11) of the depressurization rate are set in the etching apparatus (S800), when the button for starting the control of the vacuuming speed on the screen of the control computer is pressed, the opening degree of the valve can be automatically controlled.

After the start of control (S802) is instructed to the control computer, the lock chamber is put into an atmospheric pressure state (S804, S806). Then, a vacuuming provisional recipe is read (S808). When there is no detailed provisional recipe, vacuuming is carried out by setting the opening degree to 50% as an initial value (S810). Then the depressurization rate is judged (S812). When it is outside the range, the vacuuming recipe is changed (S816). That is, when the depressurization rate exceeds a predetermined value, the opening degree of the valve is made small and when the depressurization rate falls below the predetermined value, the opening degree is made large. Venting is carried out again (S806), then, by using a newly prepared recipe, vacuuming of the lock chamber is carried out (S810), and testing is repeated until the depressurization rate falls within the predetermined range. Data obtained when the depressurization rate falls within the predetermined range are recorded as a control recipe (vacuuming recipe) and set (S814). Since this test is completed by repeating vacuuming and venting about 10 times, when the venting time is set to 5 seconds and the vacuuming time is set to 10 seconds, the test is completed in a few minutes.

A description is subsequently given of the value of the upper limit depressurization rate d11 required for the suppression of rolling foreign particles. It is desired that the upper limit depressurization rate d11 should be set to about 80 kPa/s or less and 800 LkPa/s or less. The reason that the two measures kPa/s and LkPa/s are used is that a gas flow close to a wall relatively far from an exhaust port and a gas flow relatively close to the exhaust port must be taken into consideration.

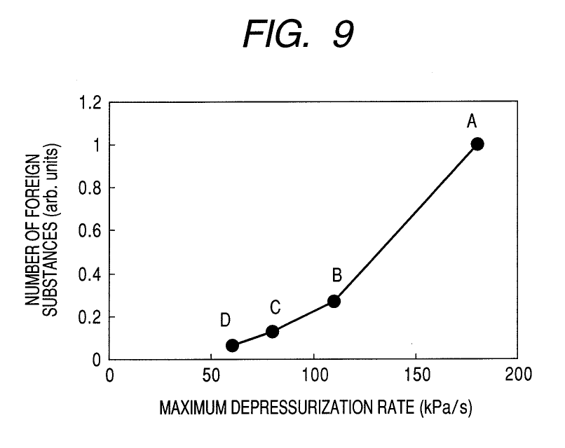

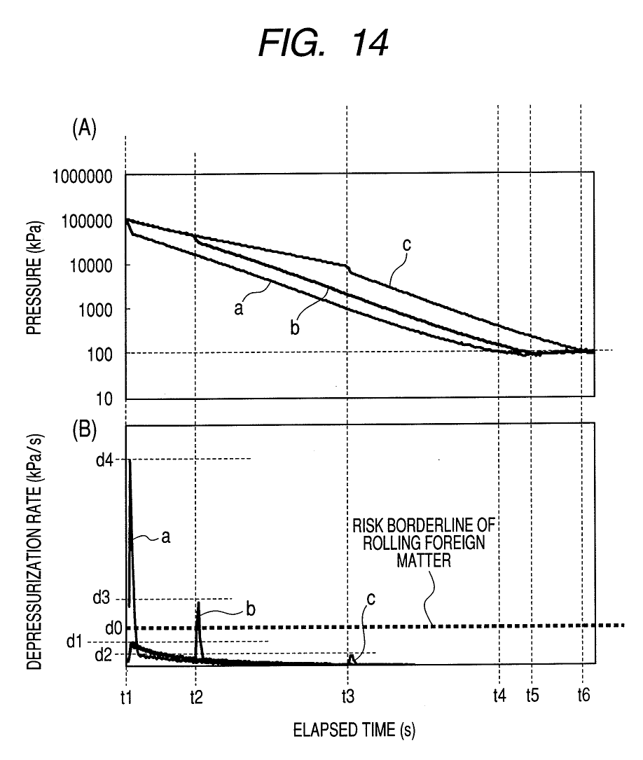

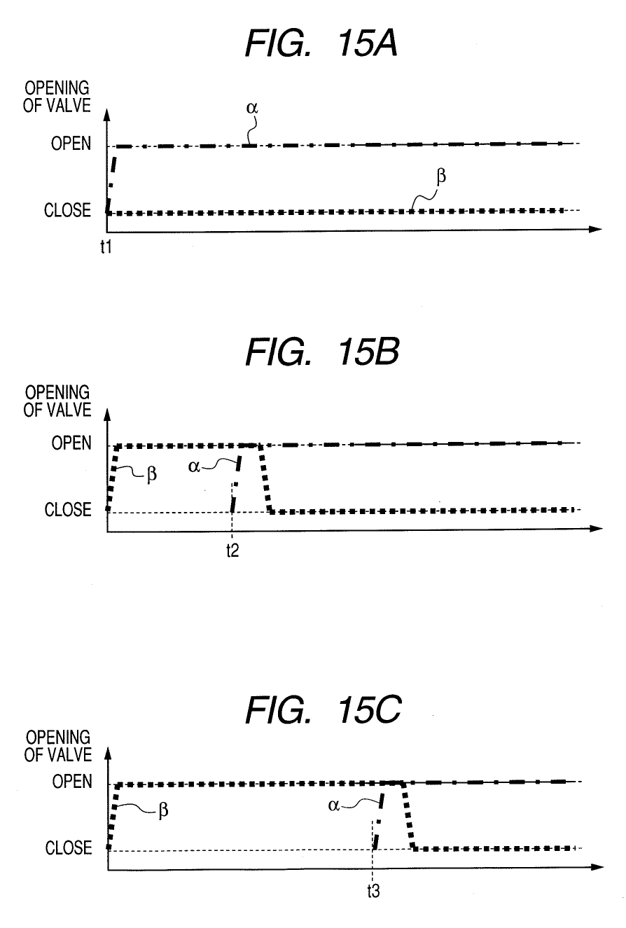

The reason that the upper limit declaration speed d11 is set to 80 kPa/s or less is first explained. FIG. 9 shows the relationship between the depressurization rate and the number of foreign particles dropped on a wafer installed in the lock chamber, which is actually measured by experiments. The maximum depressurization rate on the horizontal axis shows a depressurization rate at a pressure range at which the depressurization rate is the highest when the pressure is reduced from the atmospheric pressure to vacuum at the time of vacuuming. It substantially corresponds to a depressurization rate for reducing the pressure from the atmospheric pressure to about ½ of the atmospheric pressure. The point “A” in FIG. 9 indicates the number of foreign substances dropped on the wafer installed in the lock chamber when quick evacuation equivalent to “a” in FIG. 14 is carried out. When this is taken as the standard, to reduce the number of foreign particles adhered to the wafer by 80%, it is understood that the depressurization rate must be set to about 80 kPa/s or less at the point “C” in FIG. 9.

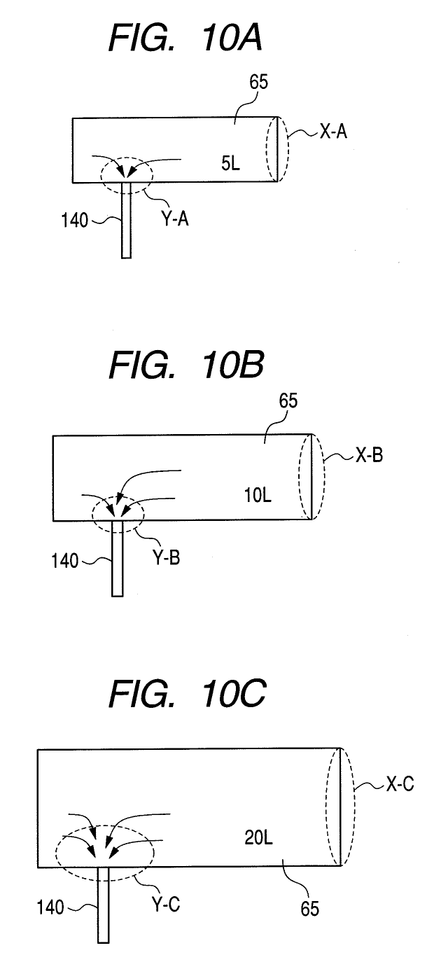

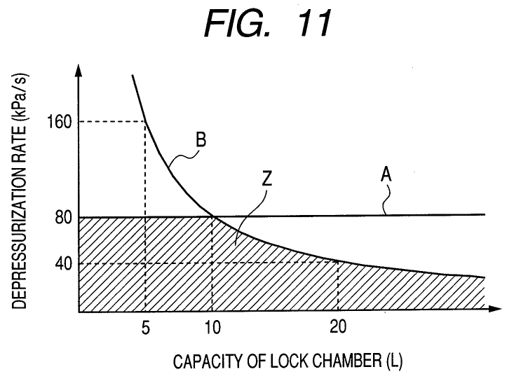

800 LkPa/s as the index of the upper limit depressurization rate d11 is explained with reference to FIG. 10 and FIG. 11. FIG. 10 show differences in gas flow velocity when the capacity of the lock chamber is 5 liters (FIG. 10A), 10 liters (FIG. 10B) and 20 liters (FIG. 10C). FIG. 9 shows the experimental results obtained from the same lock chamber as in FIG. 10B having a capacity of about 10 liters. It is supposed that vacuuming is carried out at a constant depressurization rate from the atmospheric pressure to ½ of the atmospheric pressure.

For instance, when vacuuming is carried out at a rate of, for example, 80 kPa/s, the flow rate of gas exhausted from the exhaust port is 8 L/s at the atmospheric pressure in FIG. 10B. The computation expression is as follows:

10 [L]×80 [kPa/s]/100 [kPa]=8 [L/s]

When the capacity is 5 liters (FIG. 10(A)) and the depressurization rate remains the same, the computation expression is as follows:

5 [L]×80 [kPa/s]/100 [kPa]=4 [L/s]

The gas flow rate becomes half. As a matter of course, when the capacity is 20 liters in FIG. 10C, the flow rate of exhaust gas near the exhaust port becomes 16 L/s which is double as that when the capacity is 10 liters.

The gas flow rates near Y-A, Y-B and Y-C are proportionate to the amount of exhaust gas, that is, the capacity of the lock chamber when the depressurization rate expressed by kPa/s is the same. Therefore, to set the gas flow rate to the same value as the gas flow rate near Y-B in the lock chamber having a capacity of 10 liters shown in FIG. 10B, the depressurization rate x in the lock chamber having a capacity of 20 liters is obtained from the following expression:

20 [L]×x [kPa/s]/100 [kPa]=8 [L/s]

x=40 kPa/s

Thus, the depressurization rate x must be halved. On the other hand, in the case of a lock chamber having a capacity of 5 liters, the depressurization rate becomes 160 kPa/s which is double the above figure.

In areas sufficiently away from the exhaust port, for example, wall areas X-A, X-B and X-C in FIG. 10, the gas flow rate does not depend much on the capacity of the lock chamber. If the depressurization rate expressed by kPa/s is constant, there is no big change.

All described above are put together and shown in FIG. 11. The straight line “A” in FIG. 11 is related to the generation of foreign matter at a position away from the exhaust port such as the area X in FIG. 10 and shows required 80 kPa/s as the upper limit depressurization rate d11. On the other hand, the curve “B” in FIG. 11 is related to the generation of foreign matter near the area Y in FIG. 10 close to the exhaust port and shows required 80 L·kPa/s as the upper limit depressurization rate d11. A depressurization rate of 80 kPa/s or less and 800 L·kPa/s or less corresponds to the area Z in FIG. 11. That is, in order to reduce the number of foreign substances by 80% or more based on the results of FIG. 9, the depressurization rate must be set to 80 kPa/s or less when the capacity is 10 liters or less or to 800 L·kPa/s or less (a value expressed by kPa/s changes according to the capacity of the lock chamber) when the capacity is 10 liters or more.

It has already been stated that the target reduction of the number of foreign substances is a 80% reduction with reference to FIG. 9. When the definition of the upper limit depressurization rate d11 is generalized by taking into account a case where the target reduction of the total amount of generated foreign particles differs from the above figure, d11 is “a depressurization rate value or less expressed by kPa/s defined by taking into consideration the suppression of rolling foreign matter at a position away from the exhaust port and a depressurization rate or less expressed by L·kPa/s defined by taking into consideration the suppression of rolling foreign matter at a position close to the exhaust port”.

### Embodiment 2

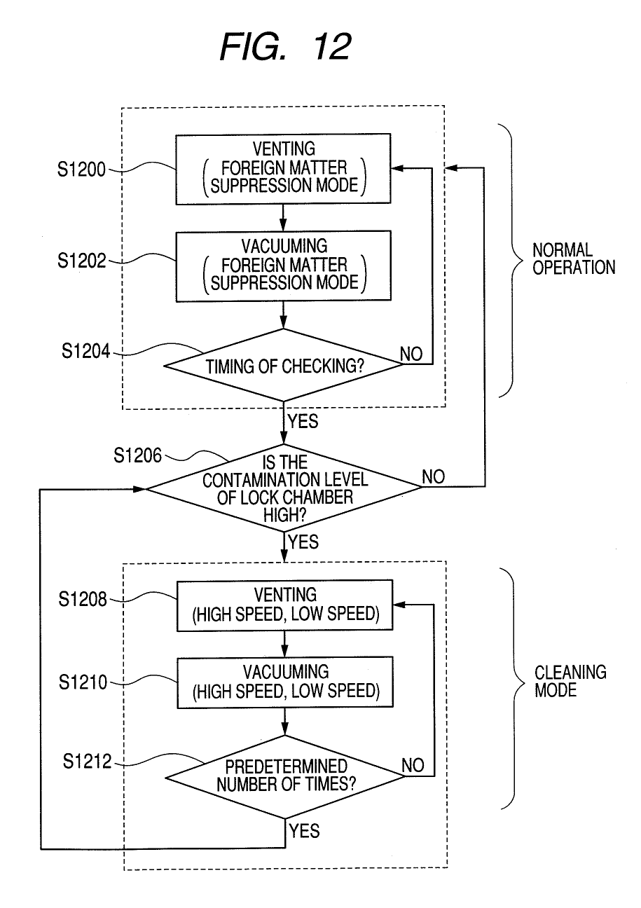

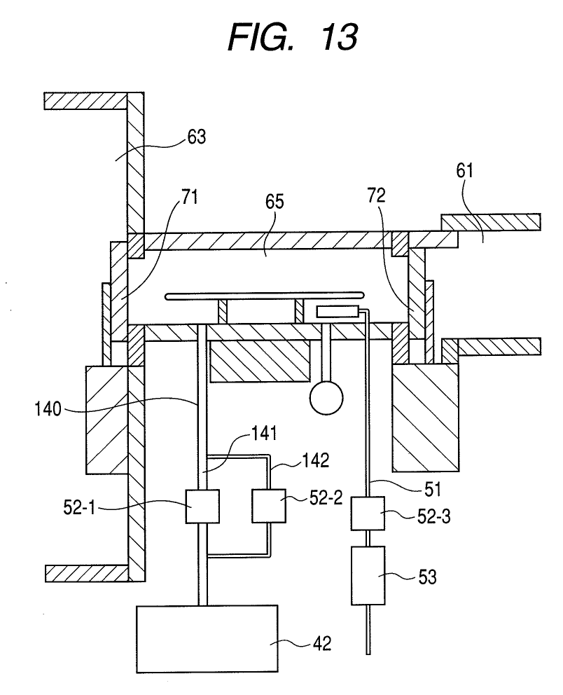

A description is subsequently given of the method of cleaning the lock chamber making use of an advantage that an opening variable valve is mounted as Embodiment 2 of the present invention. FIG. 12 shows the procedures of normal operation and cleaning operation. At the time of normal operation, venting (S1200) and evacuation (S1202) are carried out in the lock chamber to carry a wafer. To check the amount of foreign matter regularly at predetermined intervals (S1204), a test wafer is carried and the number of foreign substances dropped on the wafer is counted by wafer surface inspection to check the level of contamination by foreign particles (S1206). When the amount of foreign matter exceeds an acceptable value, cleaning operation is carried out. In this cleaning operation, venting is first carried out at a high speed (S1208), and vacuuming (S1210) is carried out by reducing the pressure as quickly as possible to stir up foreign matter in the lock chamber intentionally so that it can be exhausted by the dry pump 44.

Evacuation characteristics at this point are expressed as the condition “a” in FIG. 14. When this venting speed is made higher than that for normal operation at this point, the cleaning effect may be enhanced. After evacuation by quick depressurization and venting are repeated a predetermined number of times (S1212), venting (S1208) and evacuation (S1210) are repeated a predetermined number of times to carry out venting and evacuation at the same low speed as that for normal operation. Finally, the end of cleaning is judged by using a wafer for checking the amount of foreign matter (S1206). After cleaning, the routine goes back to normal operation.

As means of judging the end point of cleaning, a particle counter for counting foreign particles may be installed in the exhaust line 140 to judge the end point of cleaning, besides the above means using a foreign matter inspection wafer.

What is claimed is:

1. A vacuum processing apparatus comprising:
a lock chamber capable of switching between a vacuum atmosphere and an ambient atmosphere;
a vacuum pump for reducing the inside pressure of the lock chamber;
a valve installed in an exhaust line for connecting the vacuum pump to the lock chamber; and
control means for controlling the opening degree of the valve,
wherein the exhaust line is composed of only a single line, the valve installed in the exhaust line is composed of only a single opening variable valve, and
wherein the control means controls the opening degree of the valve from a totally closed state to a fully opened state while it controls a depressurization rate to a substantially constant value so as to reduce the inside pressure of the lock chamber from the ambient atmosphere.

2. The vacuum processing apparatus according to claim 1, wherein the control means controls the opening degree of the valve to ensure that the depressurization rate of the inside of the lock chamber becomes lower than a predetermined upper limit depressurization rate and larger than a predetermined lower limit depressurization rate based on a measurement result of the inside pressure of the lock chamber.

3. The vacuum processing apparatus according to claim 2, wherein the control means controls the opening degree of the valve to ensure that the upper limit depressurization rate becomes 80 kPa/s or less and 800 L·kPa/s or less to reduce the inside pressure of the lock chamber.

4. The vacuum processing apparatus according to claim 1, wherein the control means controls the opening degree of the valve to ensure that the depressurization rate for reducing the inside pressure of the lock chamber falls below a value expressed by kPa/s which indicates suppression of rolling foreign matter at a position away from an exhaust port and does not depend on the capacity of the lock chamber and a value expressed by L·kPa/s which indicates suppression of rolling foreign matter at a position close to the exhaust port and depends on the capacity L of the lock chamber.

5. A vacuum processing apparatus comprising:
a lock chamber:
a vacuum pump for reducing the inside pressure of the lock chamber;
a valve installed in an exhaust line for connecting the vacuum pump to the lock chamber; and
control means for controlling the opening degree of the valve,
wherein the control means controls a depressurization rate for reducing the inside pressure of the lock chamber to 80 kPa/s or less and 800 L·kPa/s or less by controlling the opening degree of the valve according to the inside pressure of the lock chamber.

6. A vacuum processing apparatus comprising:
a vacuum processing chamber;
a lock chamber connected to the vacuum processing chamber and capable of switching between a vacuum atmosphere and an ambient atmosphere;
a vacuum pump for reducing the inside pressure of the lock chamber;
a valve installed in an exhaust line for connecting the vacuum pump to the lock chamber; and
control means for controlling the opening degree of the valve,
wherein the exhaust line is composed of only a single line, the valve installed in the exhaust line is composed of only a single opening variable valve, and
wherein the control means controls venting and evacuation at the time of normal operation for carrying a sample to be processed to and from the vacuum processing chamber, controls the opening degree of the valve from a totally closed state to a fully opened state while it controls a depressurization rate to a substantially constant value to reduce the inside pressure of the lock chamber from the ambient atmosphere at the time of controlling evacuation, and controls the opening degree of the valve to reduce the inside pressure of the lock chamber from the atmospheric pressure quickly during cleaning operation during which the sample to be processed is not carried so as to clean the inside of the lock chamber.
